(19) United States
(12) Patent Application Publication
(10) Pub. No.: US 2009/0148982 A1
(43) Pub. Date: Jun. 11, 2009

(54) Method of Manufacturing Compound Semiconductor Devices

(75) Inventors: Gyu-Chul Yi, Pohang-Shi (KR); Sung-Jin An, Pohang-Shi (KR); Yong-Jin Kim, Gumi-Shi (KR); Dong-Kun Lee, Gumi-Shi (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignees: SILTRON INC., Gumi-Shi (KR); POSTECH FOUNDATION, Pohang-Shi (KR)

(21) Appl. No.: 12/357,205

(22) Filed: Jan. 21, 2009

Related U.S. Application Data
(62) Division of application No. 11/202,126, filed on Aug. 11, 2005.

(30) Foreign Application Priority Data
Mar. 9, 2005 (KR) 10-2005-0019605

(51) Int. Cl. H01L 21/36

(52) U.S. Cl. 438/104; 438/483; 257/E21.461

(57) ABSTRACT

A compound semiconductor device and method of manufacturing the same. The method includes coating a plurality of spherical balls on a substrate and selectively growing a compound semiconductor thin film on the substrate on which the spherical balls are coated. The entire process can be simplified and a high-quality compound semiconductor thin film can be grown in a short amount of time in comparison to an epitaxial lateral overgrowth (ELO) method.

### CROSS-REFERENCE TO RELATED APPLICATIONS

This is a division of co-pending U.S. Ser. No. 11/202,126 filed Aug. 11, 2005, which claims priority under 35 USC § 119 to Korean patent application No. 10-2005-0019605 filed Mar. 9, 2005, the disclosures of both of which are incorporated herein by reference.

### BACKGROUND

1. Technical Field

Compound semiconductor devices are disclosed which have a compound semiconductor thin film grown on a substrate on which spherical balls are coated. Methods of manufacturing the same are also disclosed.

2. Description of the Related Art

Gallium nitride (GaN) is known as a material that is useful for blue light-emitting devices or high-temperature electronic devices. However, it is not easy to fabricate a GaN single-crystalline substrate. Because GaN solid has a very high melting point (72000° C.) and/or can decompose into Ga and N₂ before it melts, GaN crystals cannot be made using a typical Czochralski technique for growing crystals from a solution. Although it may be possible to form a GaN solution by applying an ultra-high voltage to the GaN solid, this method becomes problematic in terms of mass production.

Because of the increased demand for light emitting devices that emit blue wavelength light, nitride (or GaN-based) thin films have become necessary. Further, various methods are being employed to improve the luminous efficiency of the light emitting devices. In recent years, an epitaxial lateral overgrowth (ELO) method has been used to manufacture a high-quality nitride semiconductor thin film that determines internal quantum efficiency. The ELO method is applied to manufacture of high-speed devices, such as blue laser diodes using homoepitaxy, an ultraviolet (UV) laser diode, a high-temperature/high-output device, a high electron mobility transistor (HEMT), or a heterojunction bipolar transistor (HBT).

In the ELO method, stress resulting from differences in lattice constant and thermal expansion coefficient between the substrate and the GaN crystal is reduced using a “stripe-shaped” or striped SiO₂ mask. Specifically, the ELO method includes growing a GaN thin film on a substrate. The substrate and the GaN thin film are then taken out of a reactor and loaded into a deposition apparatus. A SiO₂ thin film is formed on the GaN thin film. After being unloaded from the deposition apparatus, a SiO₂ mask pattern is formed with photolithography and etching processes. Subsequently, the resultant structure is loaded again into the reactor, and then a GaN thin film is formed thereon. However, such an ELO method involves complicated processes as described above, includes numerous steps including loading and unloading and takes much time.

An example of the ELO method is disclosed in Japanese Patent Laid-Open Publication No. 2000-22212 entitled “GaN Single Crystalline Substrate and Method of Manufacturing the Same.” Also, Korean Patent Laid-Open Publication No. 10-2004-0101179 entitled “Substrate for Growing GaN, Method of Manufacturing the Same, and Method of Manufacturing GaN substrate” introduces a method of growing low-potential GaN crystals using both an ELO method and a defect mask method. In addition, Korean Patent Laid-Open Publication No. 10-2001-0020287 entitled “Enhanced Process of Manufacturing Nanoporous Silica Thin film” proposes a method of manufacturing a nanoporous insulating layer on a substrate.

### SUMMARY OF THE DISCLOSURE

A compound semiconductor device with a compound semiconductor thin film grown on a substrate on which spherical balls are coated is disclosed.

A method for manufacturing a compound semiconductor device is also disclosed in which spherical balls are coated on a substrate and a compound semiconductor thin film is selectively grown on the substrate having the coated spherical balls so that the entire manufacturing process can be simplified and the compound semiconductor thin film can be grown in a short amount of time.

A disclosed compound semiconductor device comprises: a substrate; a plurality of spherical balls arranged on the substrate; and a compound semiconductor thin film disposed between and on the spherical balls, the thin film emitting one of ultraviolet (UV) light, visible (V) light, and infrared (IR) light.

In one embodiment, the compound semiconductor device may further comprise a buffer layer disposed between the substrate and the compound semiconductor thin film in order to minimize the density of crystal defects in the compound semiconductor thin film by reducing a crystalline difference between the substrate and the compound semiconductor thin film. In a related embodiment, the compound semiconductor thin film may comprise a first compound semiconductor thin film and a second compound semiconductor thin film, wherein the first compound semiconductor thin film may be disposed on the buffer layer, and the second compound semiconductor thin film may be disposed between and on the spherical balls disposed on the first compound semiconductor thin film.

In another embodiment, the compound semiconductor thin film comprises: a buffer layer disposed between the substrate and the compound semiconductor thin film as described above; a plurality of spherical balls arranged on the compound semiconductor thin film; and a compound semiconductor thin film disposed between and on the spherical balls arranged on the compound semiconductor thin film.

In still another embodiment, the compound semiconductor thin film may further comprise at least one-layered compound semiconductor thin film stacked on the compound semiconductor thin film and formed of a different material from the compound semiconductor thin film.

A disclosed method of manufacturing a compound semiconductor device comprises: forming a plurality of spherical balls; coating the spherical balls on a substrate; growing a buffer layer on the substrate on which the spherical balls are coated; selectively growing a compound semiconductor thin film between the spherical balls; growing the clusters or islands for the compound semiconductor thin film in a lateral direction such that the clusters or islands combine into the compound semiconductor thin film on the spherical balls; and continuously growing the compound semiconductor thin film to a desired thickness.

The method may further comprise: after the compound semiconductor thin film is grown to the desired thickness, forming a plurality of spherical balls; coating the spherical balls on the compound semiconductor thin film; selectively growing a compound semiconductor thin film on the compound semiconductor thin film on which the spherical balls are coated and between the spherical balls coated on the compound semiconductor thin film; and growing the compound semiconductor thin film in a lateral direction such that combine into the compound semiconductor thin film on the spherical balls coated on the compound semiconductor thin film.

Another disclosed method of manufacturing a compound semiconductor device comprises: growing a buffer layer on a substrate; selectively growing a first compound semiconductor thin film on the buffer layer; growing the first compound semiconductor thin film in a lateral direction such that combine into the first compound semiconductor thin film; forming a plurality of spherical balls; coating the spherical balls on the first compound semiconductor thin film; selectively growing a second compound semiconductor thin film on the first compound semiconductor thin film and between the spherical balls; growing the second compound semiconductor thin film in a lateral direction such that combine into the second compound semiconductor thin film on the spherical balls; and continuously growing the second compound semiconductor thin film to a desired thickness.

### BRIEF DESCRIPTION OF THE DRAWINGS

The above and other features and advantages of the disclosed compound semiconductor devices and manufacturing methods will become apparent with reference to the attached drawings, wherein:

FIG. 1 graphically illustrates a lattice constant relative to an energy bandgap of a nitride semiconductor thin film;

FIG. 2 is a scanning electron microscope (SEM) photograph of a substrate on which SiO₂ spherical balls are coated according to a disclosed embodiment;

FIGS. 3 through 9 are cross-sectional views illustrating a compound semiconductor device and method of manufacturing the same according to disclosed embodiments;

FIGS. 10A through 10D are SEM photographs illustrating the operations of growing a nitride semiconductor thin film on a substrate on which SiO₂ spherical balls are coated according to a disclosed embodiment;

FIGS. 11A and 11B are graphs showing X-ray diffraction (XRD) rocking curves for a GaN thin film; and

FIGS. 12A and 12B are graphs showing results of measurement of low-temperature (10 K) photoluminescence (PL) for a GaN thin film.

### DETAILED DESCRIPTION OF THE PRESENTLY PREFERRED EMBODIMENTS

In the following drawings, the thickness of layers and regions may be exaggerated and other intervening layers omitted for clarity. The same reference numerals are used to denote the same elements throughout the specification.

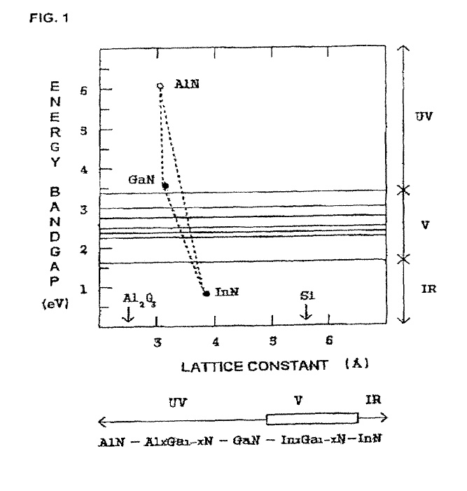

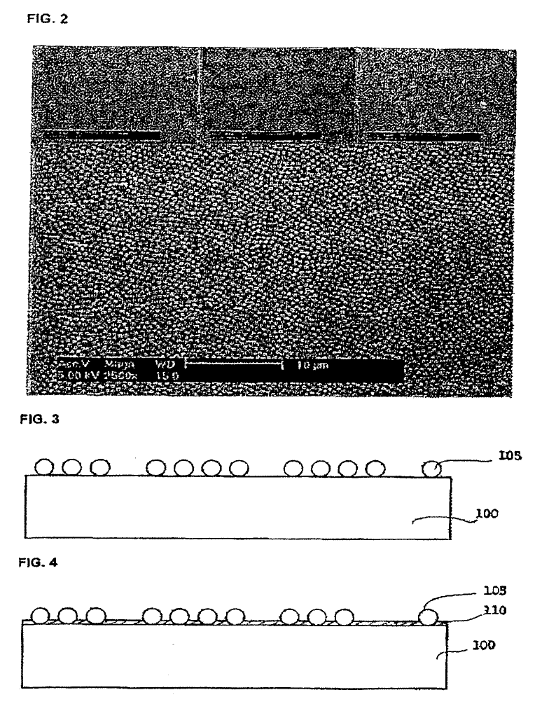

In the disclosed embodiments, a compound semiconductor thin film is grown using a selective growth process on a substrate on which spherical balls are coated. FIG. 1 is a graph showing a lattice constant relative to an energy bandgap of a nitride semiconductor thin film, and FIG. 2 is a scanning electron microscope (SEM) photograph showing a substrate on which SiO₂ spherical balls are coated according to one exemplary embodiment.

### Embodiment 1

FIGS. 3 through 7 are cross-sectional views illustrating a compound semiconductor device and method of manufacturing the same according to a first exemplary embodiment.

Referring to FIG. 3, a plurality of spherical balls 105 are made and coated on a substrate 100. The spherical balls 105 may be formed of SiO₂, Al₂O₃, TiO₂, ZrO₂, Y₂O₃—ZrO₂, CuO, Cu₂O, Ta₂O₅, PZT(Pb(Zr, Ti)O₃), Nb₂O₅, FeSO₄, Fe₃O₄, Fe₂O₃, Na₂SO₄, GeO₂, CdS, or a metal. For example, to make SiO₂ spherical balls, a first solution is made by dissolving tetraethylorthosilicate (TEOS) in anhydrous ethanol. An ammonia ethanol solution is mixed with deionized water and ethanol, thus making a second solution. Ammonia acts as a catalyst for making the spherical balls 105. The first solution is mixed with the second solution, and the mixture of the first and second solutions is stirred at a predetermined temperature for a predetermined amount of time. The spherical balls 105 are separated from the stirred mixture using a centrifugal separation process, washed using ethanol, and then redistributed in an ethanol solution. The spherical balls 105 may be made in a wide range from several nm to several tens of μm (e.g., about 10 nm to 2 μm) according to process conditions, such as growth time, temperature, and the amount of reactants. The spherical balls 105 are coated on the substrate 100 using a dip coating process or a spin coating process. FIG. 2 shows a silicon substrate on which SiO2 spherical balls are coated.

The substrate 100 may be a substrate that is formed of Al₂O₃, GaAs, spinel, InP, SiC, or Si. For example, the Al₂O₃ substrate is very stable in a high temperature environment, but its small size is not appropriate for the manufacture of large devices. The SiC substrate is also very stable in a high temperature environment and has about the same crystalline structure, lattice constant, and thermal expansion coefficient as the GaN substrate, but its price is expensive. There are a difference of 17% in lattice constant between the Si substrate and the GaN substrate and a difference of 35% in thermal expansion coefficient there between. As described above, a variety of substrates can be used for the substrate 100, and since the Si substrate enables the manufacture of large-area (about 12 inches or more) devices, the cost of production can be greatly reduced and the application of the devices can be dramatically expanded.

Referring to FIG. 4, the substrate 100 on which the spherical balls 105 are coated is loaded into a metal organic chemical vapor deposition (MOCVD) apparatus, and a buffer layer 110 is grown on the substrate 100. To form the buffer layer 110 using an MOCVD process, reactive precursors are injected into a reactor (i.e., the MOCVD apparatus) at predetermined flow rates through separate lines, thus causing a chemical reaction between the reactive precursors. In this process, the buffer layer 110 is formed to a desired thickness.

The buffer layer 110 is formed to reduce a crystalline difference between the substrate 100 and a compound semiconductor thin film which will be formed later and minimize the density of crystal defects of the compound semiconductor thin film. That is, the buffer layer 110 is used to reduce mismatch and interfacial defects between the substrate 100 and the compound semiconductor thin film. Accordingly, the buffer layer 110 may be formed of a material that has about the same crystalline characteristics as the compound semiconductor thin film and which is chemically stable. That is, the buffer layer 110 may be formed of a material, which has the same (or about the same) crystalline structure, lattice constant, or thermal expansion coefficient as the compound semiconductor thin film 115 shown in FIG. 5. Preferably, the buffer layer 110 is formed of a material, which has the same crystalline structure as the compound semiconductor thin film 115 (see FIG. 5) and makes a difference of less than 20% in lattice constant to the compound semiconductor thin film.

The buffer layer 110 may be formed of GaN, AlN, AlGaN, or a combination thereof. In this case, the reactive precursor may be TMAl, TMGa, TEGa, or GaCl₃, and a nitride source gas may be NH₃, N₂, or tertiarybutylamine(N(C₄H₉)H₂). For example, the GaN buffer layer is grown to a thickness of about 10 to 40 nm at a temperature of about 400 to 800° C., and the AlN or AlGaN buffer layer is grown to a thickness of about 10 to 200 nm at a temperature of about 400 to 1200° C. The buffer layer 110 may be optionally used according to the type of substrate, a growth apparatus (e.g., an MOCVD apparatus), or growth conditions.

Referring to FIG. 5, after the formation of the buffer layer 110, the compound semiconductor thin film 115 is grown on the substrate 100 on which the spherical balls 105 are coated. The compound semiconductor thin film 115 is grown between the spherical balls 105 on the buffer layer 110.

The compound semiconductor thin film 115 may be a Group III-V compound semiconductor thin film or a Group II-VI compound semiconductor thin film, which emits ultraviolet (UV) light, visible (V) light, or infrared (IR) light. The compound semiconductor thin film 115 may be formed of a nitride semiconductor material, for example, GaN, AlN, InN, or any combination thereof (e.g., Ga₁₋ₓAl_{1-y}In_{1-z}N, 0≦x, y, z≦1). GaN is a direct-transition wide bandgap semiconductor with a bandgap energy of 3.4 eV, which is appropriate for the application of a blue light emitting device or a high-temperature electronic device. When the compound semiconductor thin film 115 is deposited, In or Al is separately, simultaneously, or sequentially injected while growing a thin film formed of InN, AlN, InGaN, AlGaN, or InGaAlN, so that a bandgap of a compound semiconductor device can be controlled to 0.7 to 6.2 eV. It is known that the GaN thin film has a bandgap of 3.4 eV, the AlN thin film has a bandgap of 6.2 eV, and the InN thin film has a bandgap of 0.7 eV as shown in FIG. 1.

FIG. 1 shows lattice constants relative to energy bandgaps of several nitride semiconductor thin films. As can be seen from FIG. 1, AlN, which has a bandgap of 6.2 eV, emits UV light, AlₓGa₁₋ₓN(0<x<1) has a smaller bandgap than AlN but emits UV light, GaN has a bandgap of 3.4 eV smaller than AlₓGa₁₋ₓN(0<x<1), InₓGa₁₋ₓN(0<x<1) has a bandgap smaller than GaN and emits V light, and InN, which has a bandgap of 0.7 eV smaller than InₓGa₁₋ₓN(0<x<1), emits IR light.

The deposition of the compound semiconductor thin film 115 on the substrate 100 on which the spherical balls 105 are coated can be performed using, for example, an MOCVD process, a molecular beam epitaxy (MBE) process, or a hydride vapor phase epitaxy (HVPE) process.

One method of forming the compound semiconductor thin film 115 using the MOCVD process is as follows. Initially, the substrate 100 on which the spherical balls 105 are coated is loaded into a reactor, and reactive precursors are injected into the reactor using a carrier gas. Thereafter, a chemical reaction between the reactive precursors is caused at predetermined temperature and pressure, thus growing the compound semiconductor thin film 115. When the compound semiconductor thin film 115 is a nitride-based thin film, the reactive precursor may be TMAl, TMGa, TEGa, or GaCl₃, and a nitride source gas may be NH₃, N₂, or tertiarybutylamine(N(C₄H₉)H₂).

The reactor may be maintained at a temperature of 900 to 1150° C. and at a pressure of 10-5 to 2000 mmHg. The compound semiconductor thin film 115 may be grown in the form of clusters or islands on the substrate 100 on which the spherical balls 105 are grown. When the compound semiconductor thin film 115 has its own coherence stronger than a combination between the substrate 100 and the compound semiconductor thin film 115, small clusters are formed and adsorbed onto the substrate 100 to form islands. Finally, the clusters or islands combine into the continuous compound semiconductor thin film 115. In this case, the thickness of the compound semiconductor thin film 115 may be appropriately controlled according to the quality level or specification as required.

A process of forming a GaN thin film using an MOCVD method can be expressed as shown in the following reaction (1):

Ga(CH₃)₃+NH₃→Ga(CH₃)₃.NH₃ (1)

TMGa and NH₃ are injected into the reactor, thus generating Ga(CH₃)₃.NH₃.

Ga(CH₃)₃.NH₃ is pyrolyzed on the substrate 100 so that a GaN thin film can be obtained by a reaction as shown in the following reaction (2):

Ga(CH₃)₃.NH₃→GaN+nCH₄+1/2(3−n)H₂ (2)

Referring to FIG. 6, the clusters or islands grown between the spherical balls 105 are continuously grown in a lateral direction and thus, combine into the continuous compound semiconductor thin film 115. That is, the clusters or islands adsorbed onto the substrate 100 are continuously grown and combine with one another, so that the compound semiconductor thin film 115 can have a continuous shape.

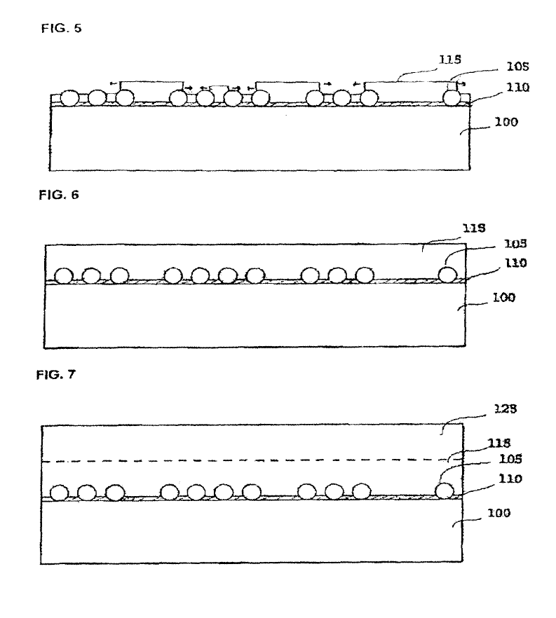

Referring to FIG. 7, a growth process is further performed on the continuous compound semiconductor thin film 115, which is selectively grown on the spherical balls 105, until a compound semiconductor thin film 125 is formed to a desired thickness. The compound semiconductor thin film 125 may be formed of the same material as or a different material from the compound semiconductor thin film 115. For example, when the compound semiconductor thin film 115 is a GaN thin film, the compound semiconductor thin film may be an AlGaN thin film. Of course, the compound semiconductor thin film 125 may include at least one layer that is formed of the same material as or a different material from the compound semiconductor thin film 115.

### Embodiment 2

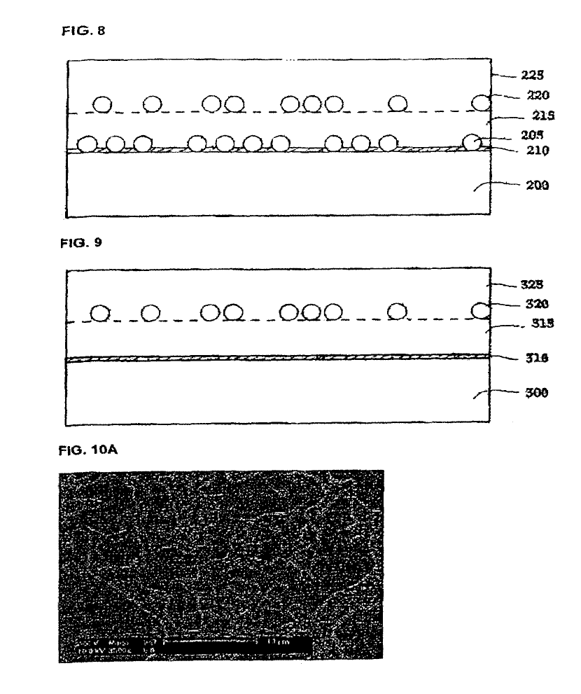

FIG. 8 is a cross-sectional view illustrating a compound semiconductor thin film and method of manufacturing the same according to a second exemplary embodiment.

Referring to FIG. 8, the processes described with reference to FIGS. 3 through 6 are performed to form a compound semiconductor thin film. That is, spherical balls 205 are made and coated on a substrate 200, a buffer layer 210 is grown, and a compound semiconductor thin film 215 is grown between the spherical balls 205 on the buffer layer 210.

The substrate 200 having the compound semiconductor thin film 215 is taken out of a reactor. Thereafter, spherical balls 220 with a size of several nm to several tens of μm are coated on the first compound semiconductor thin film 215. Next, the substrate 200 having the spherical balls 220 is loaded again into the reactor, and a second compound semiconductor thin film 225 is grown on the first compound semiconductor thin film 215 having the spherical balls 220.

### Embodiment 3

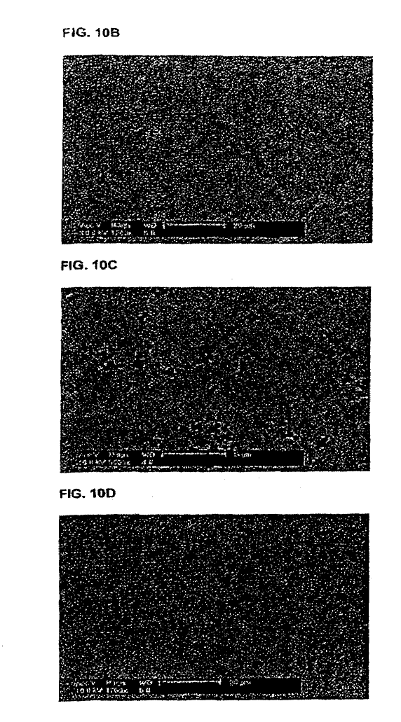

FIG. 9 is a cross-sectional view illustrating a compound semiconductor device and method of manufacturing the same according to a third exemplary embodiment.

Referring to FIG. 9, the processes described with reference to FIGS. 4 through 6 are performed, thus a buffer layer and a compound semiconductor thin film are grown on a substrate. That is, a buffer layer 310 is grown on a substrate 300, and then a compound semiconductor thin film 315 is grown on the buffer layer 310.

The substrate 300 on which the compound semiconductor thin film 315 is formed is unloaded from a reactor. Thereafter, spherical balls 320 with a size of several nm to several tens of μm are coated on the compound semiconductor thin film 315 in the same manner as described with reference to FIG. 3, and a compound semiconductor thin film 325 is grown on the compound semiconductor thin film 315 on which the spherical balls 320 are coated.

Like in the above embodiments, the method of growing a compound semiconductor thin film using a selective growth process on a substrate on which spherical balls are grown can simplify the entire process in comparison to a conventional ELO process, enables the growth of a high-quality compound semiconductor thin film, and also greatly shorten the time taken to grow the compound semiconductor thin film.

Also, in the above embodiments, a thin film can be deposited while injecting different kinds of materials (i.e., at least one selected from the group consisting of Si, Ge, Mg, Zn, O, Se, Mn, Ti, Ni, and Fe) into a reactor according to purposes, so that a compound semiconductor thin film to which a different kind of material is added can be obtained. These different kinds of materials may be optionally added in order to change the electrical, optical, or magnetic properties of the compound semiconductor thin film. The different kinds of materials can be added using an in-situ doping process, an ex-situ doping process, or an ion implantation process. The in-situ doping process is to add a different kind of material during the growth of a thin film, whereas the ex-situ doping process is to inject a different kind of material into a compound semiconductor thin film using a thermal or plasma treatment process after the compound semiconductor thin film is grown. Also, in the ion implantation process, a different kind of material is accelerated and collides with a compound semiconductor thin film so that the different kind of material is implanted into the thin film.

In another approach, after a compound semiconductor thin film is formed on a substrate on which spherical balls are coated, a thick compound semiconductor layer may be deposited using an HVPE technique on the compound semiconductor thin film that serves as a substrate. The HVPE technique is one of vapor deposition methods, in which gases are supplied to a substrate so that crystals are grown by a reaction between the gases. Once the thick compound semiconductor layer is formed using the HVPE technique, the compound semiconductor thin film used as the substrate is cut or a region except the thick compound semiconductor layer is removed by a polishing or grinding process. Then, only a uniform and good-quality compound semiconductor layer, which is grown on the substrate, can be selected and used.

A method of forming the foregoing thick compound semiconductor layer (e.g., a GaN thick layer) on a compound semiconductor thin film using an HVPE technique is as follows. Initially, a container containing Ga is loaded into a reactor and heated using a heater installed around the container to form a Ga solution. A reaction between the Ga solution and HCl occurs, thus generating a GaCl gas. This reaction can be expressed as shown in the following reaction (3):

Ga(l)+HCl(g)→GaCl(g)+1/2H₂(g) (3)

The GaCl gas reacts with NH₃, thus producing a GaN layer. This reaction can be expressed as shown in the following reaction (4):

GaCl(g)+NH₃→GaN+HCl(g)+H₂ (4)

The unreacted gas is exhausted by a reaction expressed in the following reaction (5):

HCl(g)+NH₃→NH₄Cl(g) (5)

The HVPE technique enables the growth of a thick layer at a high rate of about 100 μm/hr and results in high productivity.

### Experimental Example 1

To make spherical balls, tetraethylorthosilicate (TEOS) of 0.17 mol (7.747 ml) was dissolved in anhydrous ethanol (12.253 ml), thus making a first solution. An ammonia ethanol solution of 2.0 mol (100 ml) was mixed with deionized water of 7.5 mol (27 ml) and ethanol (53 ml), thus making a second solution. The first and second solutions were mixed to form a mixture having a total volume of 200 ml. The mixture was stirred at a temperature of about 30° C. for 5 hours. Then, the spherical balls were separated from the stirred mixture through a centrifugal separation process at 12000 rpm, washed using ethanol, and redistributed in an ethanol solution, thereby making the spherical balls. In this case, the spherical balls have an average diameter of about 0.5 μm (i.e. 500 nm) as shown in the SEM photograph of FIG. 2. The spherical balls can be made in a wide range from 10 nm to 2 μm according to process conditions, such as growth time, temperature, and the amount of reactants.

The SiO₂ spherical balls with a size of 0.5 μm were coated on a Si substrate (e.g., a Si substrate that is sliced in plane (111)) using an apparatus, such as a dip coater or a spin coater. As a specific example, the SiO₂ balls contained in the ethanol solution were dropped on the Si substrate using a syringe and coated on the Si substrate for 5 to 120 seconds at a rate of 1000 to 3500 rpm using a spin coater. The density of the SiO₂ balls can be controlled by repeating the coating process several times.

After the SiO₂ spherical balls were coated on the Si substrate, the resultant structure was loaded into an MOCVD apparatus and an AlN buffer layer was grown at a temperature of 1150° C. for 10 minutes to have a thickness of 100 nm. In more detail, TMAl gas and NH₃ gas were injected at flow rates of 30 and 1500 sccm, respectively, through separate lines into a reactor. In this case, H₂ gas was used as a carrier gas. While the reactor was being maintained at a pressure of 100 torr and a temperature of 1150° C., a chemical reaction between the reactive precursors (TMAl and NH₃ gases) was caused for 10 minutes, thus the AlN buffer layer with a thickness of about 70 to 100 nm was grown between the 500-nm SiO₂ balls on the Si substrate, as shown in FIG. 4.

After the AlN buffer layer was formed, the substrate was cooled off to a temperature of 1060° C., and a GaN thin film was grown between the SiO₂ spherical balls and on the SiO₂ spherical balls (refer to FIGS. 10A through 10D). In more detail, to form the GaN thin film, TMGa gas and NH₃ gas were injected at flow rates of 4.2 and 1500 sccm, respectively, through separate lines into the reactor, and H₂ gas was used as a carrier gas. While the reactor was being maintained at a pressure of about 100 torr and a temperature of 1060° C., a chemical reaction between the reactive precursors (TMGa and NH₃ gases) was caused, thus the GaN thin film was grown as shown in FIG. 5. As explained above with reference to FIGS. 6 and 7, a selective growth process was further performed so that GaN crystals between the SiO₂ spherical balls were grown in a lateral direction for 40 minutes or more. As a result, a uniform GaN thin film could be obtained. In this case, the growth rate of the GaN thin film was about 1 μm/hour.

FIGS. 10A through 10D are SEM photographs illustrating the operations of growing a nitride semiconductor thin film on a substrate on which SiO₂ spherical balls are coated according to an exemplary embodiment of the present invention. Specifically, FIG. 10A is a SEM photograph showing a case where a GaN thin film is grown for about 30 minutes, FIG. 10B is a SEM photograph showing a case where the GaN thin film is grown for about 50 minutes, FIG. 10C is a SEM photograph showing the GaN thin film is grown for about 60 minutes, and FIG. 10D is a SEM photograph showing a case where the GaN thin film is grown for more than 60 minutes until the GaN thin film completely covers the SiO₂ balls.

### Experimental Example 2

In the present exemplary example, SiO₂ spherical balls were coated on a Si substrate like in the first Experimental example, and then a buffer layer formed of AlN/AlGaN was formed. In the case of the AlN buffer layer, TMAl gas and NH₃ gas were injected at flow rates of 30 and 1500 sccm, respectively, through separate lines into a reactor using an H₂ carrier gas. While the reactor was being maintained at a pressure of 100 torr and a temperature of about 1150° C., a chemical reaction between the reactive precursors (TMAl and NH₃) was caused for 10 minutes, thus the AlN layer was grown. Also, in the case of the AlGaN buffer layer, TMAl gas, TMGa gas, and NH₃ gas were injected at flow rates of 10, 4.2, and 1500 sccm, respectively, through separate lines into the reactor using an H₂ carrier gas. While the reactor was being maintained at a pressure of 100 torr and a temperature of 1100° C., a chemical reaction between the reactive precursors (TMAl, TMGa, and NH₃) was caused for 10 minutes, thus the AlGaN buffer layer was grown.

After the AlN/AlGaN buffer layer was formed, a GaN thin film was grown for 60 minutes like in the first Experimental example. Thereafter, TMAl gas, TMGa gas, and NH₃ gas were injected at flow rates of 10, 4.2, and 1500 sccm, respectively, through separate lines into the reactor using an H₂ carrier gas. Then, while the reactor was being maintained at a pressure of 100 torr and a temperature of about 1100° C., a chemical reaction between the reactive precursors (TMAl, TMGa, and NH3) was carried out for 10 minutes, thus an AlGaN thin film was grown on the GaN thin film.

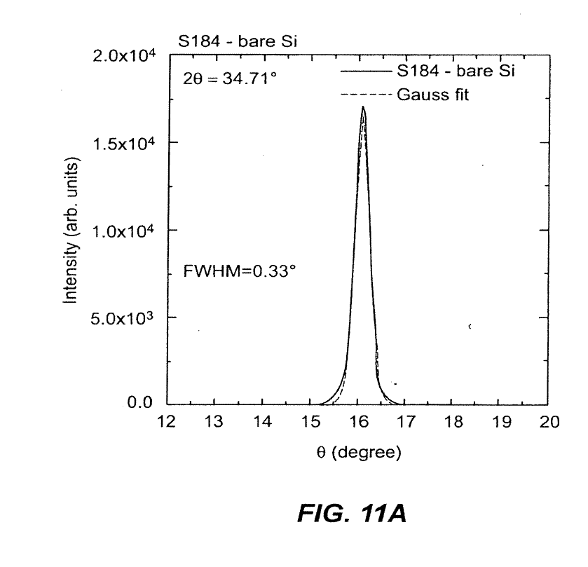

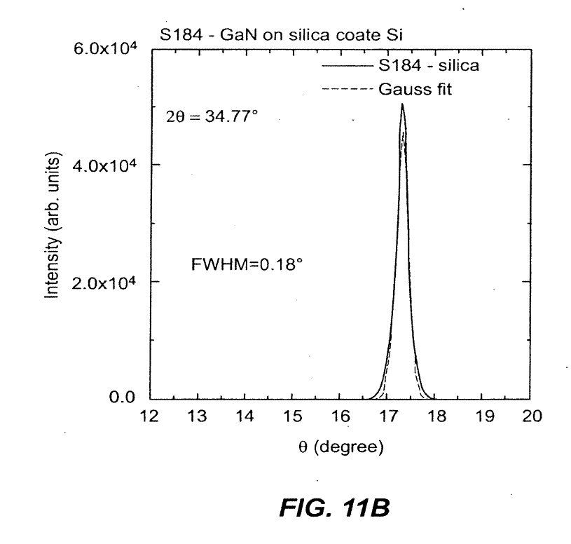

FIGS. 11A and 11B are graphs showing X-ray diffraction (XRD) rocking curves for a GaN thin film. The XRD is used to analyze the crystalline structure of a thin film based on a diffraction peak obtained by measuring values for a rocking curve. Specifically, FIG. 11A is an XRD rocking curve in a case where a GaN thin film is grown on a Si substrate on which SiO₂ balls are not coated, and FIG. 11B is an XRD rocking curve in a case where a GaN thin film is grown for 90 minutes on a Si substrate on which 500-nm SiO₂ balls are coated according to the above-described first Experimental example.

Referring to FIGS. 11A and 11B, full width half maximum (FWHM) of the XRD rocking curve of the GaN thin film grown on the Si substrate on which the SiO₂ spherical balls are not coated was 0.33°, while FWHM of the XRD rocking curve of the GaN thin film selectively grown on the Si substrate on which the SiO₂ spherical balls are coated was 0.18°. From the above result, it can be seen that the GaN thin film, which is selectively grown on the Si substrate on which the SiO₂ balls are coated, is much superior in quality to the GaN thin film grown on the Si substrate on which no SiO₂ balls are coated.

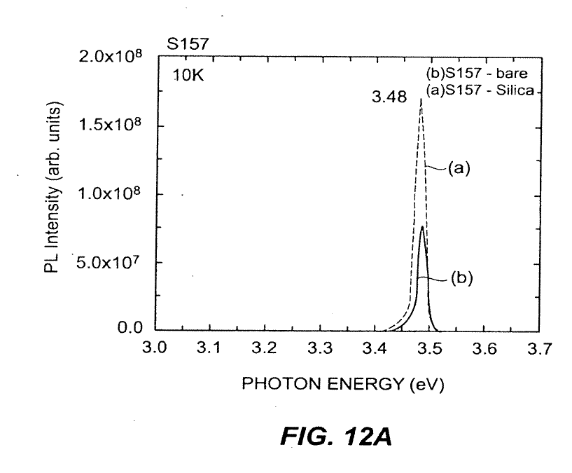

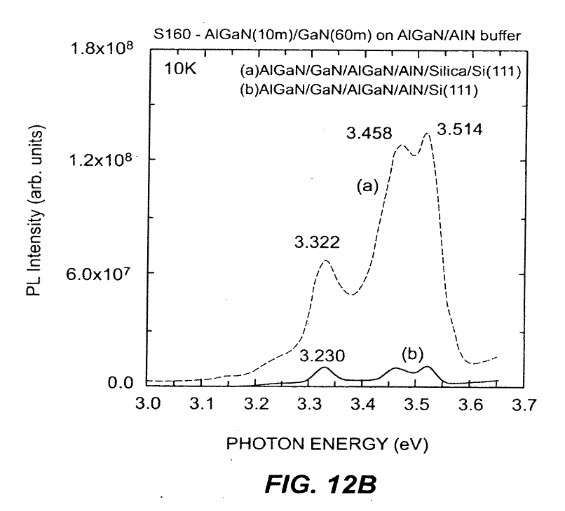

FIGS. 12A and 12B are graphs showing results of measurement of low-temperature (10 K) photoluminescence (PL) for a GaN thin film. The PL of the GaN layer was measured using the 325-nm wavelength of a He—Cd laser as a light source, and the optical characteristic of a material was appreciated by the recombination of electrons and holes within a bandgap. In FIG. 12A, curve (a) exhibits a PL peak in a case where a GaN thin film was grown for 60 minutes on a Si substrate on which 500-nm SiO₂ balls were coated according to the above-described first Experimental example, and curve (b) exhibits a PL peak in a case where a GaN thin film was grown for 60 minutes on a Si substrate on which SiO₂ balls were not coated. In FIG. 12B, curve (a) exhibits a PL peak in a case where a GaN thin film is grown on a Si substrate on which 500-nm SiO₂ balls are coated and an AlGaN thin film was grown on the GaN thin film according to the second Experimental example, and curve (b) exhibits a PL peak in a case where a GaN thin film was grown for 60 minutes on a silicon substrate on which SiO₂ balls are not coated.

Referring to FIG. 12A, which shows PL measurements obtained at a low temperature of 10K, the PL intensity of the GaN thin film that was selectively grown on the silicon substrate on which SiO₂ balls were coated is more than twice as high as that of the GaN thin film that was grown by a conventional method on the silicon substrate on which no SiO₂ balls are coated.

Accordingly, it can be confirmed that compound semiconductor thin films, which is selectively grown on a substrate on which spherical balls are coated according to the disclosed exemplary embodiments, are of excellent quality as shown in FIGS. 12A and 12B.

Thus, a GaN thin film is selectively grown on a substrate on which spherical balls are coated. More specifically, the spherical balls are coated on the substrate, the substrate is loaded into an MOCVD apparatus, a buffer layer is grown on the substrate, and then a compound semiconductor thin film is selectively grown between the spherical balls. In this method, a high-quality GaN thin film can be grown in a shorter amount of time in comparison to a conventional ELO method.

While only certain embodiments have been shown and described, it will be understood by those of ordinary skill in the art that various changes in form and details may be made therein without departing from the spirit and scope of this disclosure or the following claims.

What is claimed is:

1. A method of manufacturing a compound semiconductor device, comprising:
forming a plurality of spherical balls;
coating the spherical balls onto a substrate;
growing a buffer layer on the substrate on which the spherical balls are coated;
selectively growing a compound semiconductor thin film between the spherical balls;
growing the compound semiconductor thin film in a lateral direction so that it grows on the spherical balls; and
continuously growing the compound semiconductor thin film to a desired thickness.

2. The method according to claim 1, further comprising:
after continuously growing the compound semiconductor thin film to the desired thickness,
forming a plurality of spherical balls;
coating the spherical balls onto the compound semiconductor thin film;
selectively growing another compound semiconductor thin film on the compound semiconductor thin film on which the spherical balls are coated and between the spherical balls; and
growing for the compound semiconductor thin film in a lateral direction and on the spherical balls.

3. A method of manufacturing a compound semiconductor device, compnsing:
growing a buffer layer on a substrate;
selectively growing a first compound semiconductor thin film on the buffer layer;
growing the clusters or islands for the first compound semiconductor thin film in a lateral direction such that combine into the first compound semiconductor thin film;
forming a plurality of spherical balls;
coating the spherical balls onto the first compound semiconductor thin film;
selectively growing a second compound semiconductor thin film on the first compound semiconductor thin film and between the spherical balls;
growing for the second compound semiconductor thin film in a lateral direction and on the spherical balls; and
continuously growing the second compound semiconductor thin film to a desired thickness.

4. The method according to claim 1, wherein each of the spherical balls has a diameter in the range of from about 10 nm to about 2 μm.

5. The method according to claim 1, wherein the spherical balls are formed of a material selected from the group consisting of SiO₂, Al₂O₃, TiO₂, ZrO₂, Y₂O₃—ZrO₂, CuO, Cu₂O, Ta₂O₅, PZT(Pb(Zr, Ti)O₃), Nb₂O₅, FeSO₄, Fe₃O₄, Fe₂O₃, Na₂SO₄, GeO₂, CdS, and a metal.

6. The method according to claim 1, wherein the forming of the spherical balls comprises:
making a first solution by dissolving tetraethylorthosilicate (TEOS) in anhydrous ethanol;
making a second solution by mixing an ammonia ethanol solution with deionized water and ethanol;
mixing the first and second solutions and stirring the mixture of the first and second solutions at a predetermined temperature for a predetermined amount of time;
separating spherical balls from the stirred mixture using a centrifugal separation process; and
forming the spherical balls by distributing the separated spherical balls in an ethanol solution.

7. The method according to claim 1, wherein the buffer layer is formed of a material selected from the group consisting of GaN, AlN, AlGaN, and combinations thereof with a thickness in the range of from about 10 to about 200 nm, to minimize a density of crystal defects of the compound semiconductor thin film by reducing a crystalline difference between the substrate and the compound semiconductor thin film.

8. The method according to claim 1, wherein the growing of the buffer layer comprises:
maintaining a reactor at constant pressure and temperature;
injecting reactive precursors at predetermined flow rates through separate lines into the reactor; and
growing a buffer layer to a desired thickness by causing a chemical reaction between the reactive precursors in the reactor.

9. The method according to claim 8, wherein the buffer layer is grown while the reactor is being maintained at a temperature in a range of from about 400 to about 1200° C.

10. The method according to claim 8, wherein the reactive precursors include a first reactive precursor, which is selected from the group consisting of TMAl, TMGa, TEGa, and GaCl₃, and a second reactive precursor, which is selected from the group consisting of NH₃, N₂, and tertiarybutylamine(N(C₄H₉)H₂), and the buffer layer is formed of one selected from the group consisting of GaN, AlN, AlGaN, and combinations thereof.

11. The method according to claim 1, wherein the selectively growing of the compound semiconductor thin film between the spherical balls comprises:
maintaining a reactor at constant pressure and temperature;
injecting reactive precursors at predetermined flow rates through separate lines into a reactor; and
growing a compound semiconductor thin film by causing a chemical reaction between the reactive precursors in the reactor.

12. The method according to claim 11, wherein the compound semiconductor thin film is grown while the reactor that is maintained at a temperature in a range of from about 900 to about 1150° C.

13. The method according to claim 11, wherein the reactive precursors include a first reactive precursor, which is selected from the group consisting of TMAl, TMGa, TEGa, and GaCl₃, and a second reactive precursor, which is selected from the group consisting of NH₃, N₂, and tertiarybutylamine(N(C₄H₉)H₂), and the compound semiconductor thin film is formed of a material selected from the group consisting of GaN, AlN, AlGaN, and combinations thereof.

14. The method according to claim 1, wherein the compound semiconductor thin film further contains at least one material selected from the group consisting of Si, Ge, Mg, Zn, O, Se, Mn, Ti, Ni, and Fe.

15. The method according to claim 1, wherein the substrate is formed of a material selected from the group consisting of Al₂O₃, GaAs, spinel, InP, SiC, and Si.
